(19) United States
(12) Patent Application Publication
(10) Pub. No.: US 2016/0189931 A1
(43) Pub. Date: Jun. 30, 2016

(54) PLASMA PROCESSING APPARATUS AND METHOD FOR DETERMINING REPLACEMENT OF MEMBER OF PLASMA PROCESSING APPARATUS

(71) Applicant: TOKYO ELECTRON LIMITED, Tokyo (JP)

(72) Inventor: Toshihisa NOZAWA, Miyagi (JP)

(73) Assignee: TOKYO ELECTRON LIMITED, Tokyo (JP)

(21) Appl. No.: 14/975,238

(22) Filed: Dec. 18, 2015

(30) Foreign Application Priority Data
Dec. 25, 2014 (JP) 2014-262848

(51) Int. Cl. H01J 37/32; C23C 16/52; C23C 16/455; C23C 16/50

(52) U.S. Cl. CPC H01J 37/3244; C23C 16/50; C23C 16/52; C23C 16/455; H01J 37/32009; H01J 2237/3321

(57) ABSTRACT

Disclosed is a plasma processing apparatus including a processing container configured to air-tightly accommodate a substrate; and a placing table provided in the processing container and configured to place the substrate thereon. A surface of a support member that is exposed to plasma in the processing container and configured to support a top plate portion of the processing container, and a surface of a member that is exposed to plasma in the processing container and continued from the support member, are coated with different materials.

### CROSS-REFERENCE TO RELATED APPLICATIONS

This application is based on and claims priority from Japanese Patent Application No. 2014-262848 filed on Dec. 25, 2014 with the Japan Patent Office, the disclosure of which is incorporated herein in its entirety by reference.

### TECHNICAL FIELD

The present disclosure relates to a plasma processing apparatus and a method for determining replacement of a member of a plasma processing apparatus.

### BACKGROUND

In manufacturing a semiconductor device, various film forming processings, including a formation of an insulating film, or an etching processing of the insulating film, are performed within a processing container of a substrate processing apparatus such as, for example, a plasma processing apparatus. Surfaces of members exposed to plasma within the processing container, such as, for example, sidewall members that support a so-called top plate such as, for example, a quartz plate, a shower plate, or an upper electrode, or a support member that is disposed between the sidewall members to directly support the top plate, are damaged by a sputtering by the plasma generated during the processing. Further, since a reaction product originated from a reactive gas during the plasma processing is attached thereto, the members are also damaged by a cleaning using a cleaning gas such as, for example, fluorine gas, or plasma (chlorine gas plasma).

Therefore, the surface of each of the above-mentioned members that face in the processing container has conventionally been coated in advance with a film of a material having an excellent plasma resistance, for example, Y₂O₃(Japanese Patent Laid-Open Publication No. 2003-264169).

### SUMMARY

According to an aspect, the present disclosure provides a plasma processing apparatus including a processing container configured to air-tightly accommodate a substrate; and a placing table provided in the processing container and configured to place the substrate thereon. A surface of a support member that is exposed to plasma in the processing container and configured to support a top plate portion of the processing container, and a surface of a member that is exposed to plasma in the processing container and continued from the support member, are coated with different materials.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical sectional view illustrating a schematic configuration of a plasma processing apparatus according to an exemplary embodiment of the present disclosure.

FIG. 2 is a vertical sectional view illustrating members near a top plate portion in the plasma processing apparatus of FIG. 1 in an enlarged scale.

FIG. 3 is an explanatory view illustrating a processing flow of the plasma processing apparatus, a particle counter, and an analyzer.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Even if a film is excellent in plasma resistance, the film is corroded or deteriorated by being subject to irradiation of ions or radicals in the plasma for a long period of time, and dust (particles) is generated from the corroded or deteriorated portion. Then, a member coated with the film that has been corroded or deteriorated needs to be replaced. However, since all respective members have conventionally been coated with a film of the same material, attempts to identify a member with a corroded or deteriorated film have failed.

Thus, conventionally, the members within the processing container were sequentially replaced to detect particles again, and such a work were sequentially performed to identify a corroded or deteriorated point. Then, a corresponding member was replaced. Alternatively, all the members were replaced. Thus, according to the former, it took a long time until the apparatus was re-operated. Meanwhile, according to the latter, the costs increased because some members were unnecessarily replaced.

The present disclosure has been made in consideration of the problems described above, and, an object of the present disclosure is to solve the problems accompanying a replacement of a member by facilitating the identification of a member with a deteriorated or corroded film in a case where a film on surfaces of members that are in contact with each other within the processing container is deteriorated or corroded as heretofore.

According to an aspect, the present disclosure provides a plasma processing apparatus including: a processing container configured to air-tightly accommodate a substrate; and a placing table provided in the processing container and configured to place the substrate thereon. A surface of a support member that is exposed to plasma within the processing container and configured to support a top plate portion of the processing container, and a surface of a member that is exposed to plasma within the processing container and continued from the support member, are coated with different materials, respectively.

According to the present disclosure, the surface of the support member that is exposed to plasma within the processing container and configured to support the top plate portion of the processing container, and the surface of the member that is exposed to plasma in the processing container and continued from the support member, are coated with different materials, respectively. Therefore, by analyzing particles generated within the processing container, it is possible to determine that the particles are generated from the support member that supports the top plate portion, or the member that is continued from the support member, based on the kind of the component, and to thereby identify which member has a deteriorated or corroded film. In the processing container of this type of plasma processing apparatus, the plasma density is high near the top plate portion, and thus, the deterioration or corrosion of the support member that supports the top plate portion and the member continued from the support member is the most pronounced. Therefore, by the above-described identification, the identification becomes easier and a member which is necessary to replace can be replaced. As a result, the time taken until the re-operation of the apparatus may be reduced as compared with the conventional technique, or any unnecessary cost may be saved.

The top plate portion of the processing container referred to herein includes an upper electrode, a shower plate, a quartz plate, various dielectric plates, and a gas rectifying plate, which are disposed in an upper portion inside the processing container. Further, the member continued from the support member that supports the top plate portion includes, for example, a sidewall.

A gas supply port configured to supply a gas may be provided within the processing container, and a surface of the gas supply port that is exposed to plasma may be coated with a different material from that of each of the surfaces.

Further, a surface of the placing table that is exposed from an outer peripheral portion of the substrate to be exposed to plasma when the substrate is placed on the placing table, may be coated with a different material from that of each of the surfaces, that is, the surface of the support member that supports the top plate portion, the surface of the member continued from the support member, and the surface of the gas supply port.

Moreover, in a case where a baffle plate is provided within the processing container, a surface of the baffle plate that is exposed to plasma may be coated with a different material from that of each of the surfaces.

According to another aspect, the present disclosure provides a method for determining replacement of a member of the above-described plasma processing apparatus. The method includes: placing a simulation substrate on the placing table; supplying a predetermined gas into the processing container, or converting the predetermined gas into plasma in the processing container; measuring the number of particles on the simulation substrate by a particle counter; performing a component analysis of the particles on the simulation substrate when the number of particles exceeds a predetermined value, based on the measurement result; and determining that a member coated with a coating material including a component having the largest number of particles is a member to be replaced, based on the analysis result.

In this case, it may be determined that a member coated with a coating material including a component of which the number of particles exceeds a predetermined threshold is a member to be replaced, based on the analysis result.

According to the present disclosure, in the plasma processing apparatus, it is easy to identify a member in which a film on the surface is deteriorated or corroded in the processing container, and thus, the member may be replaced in a shorter time without spending any unnecessary cost, as compared with a conventional technique.

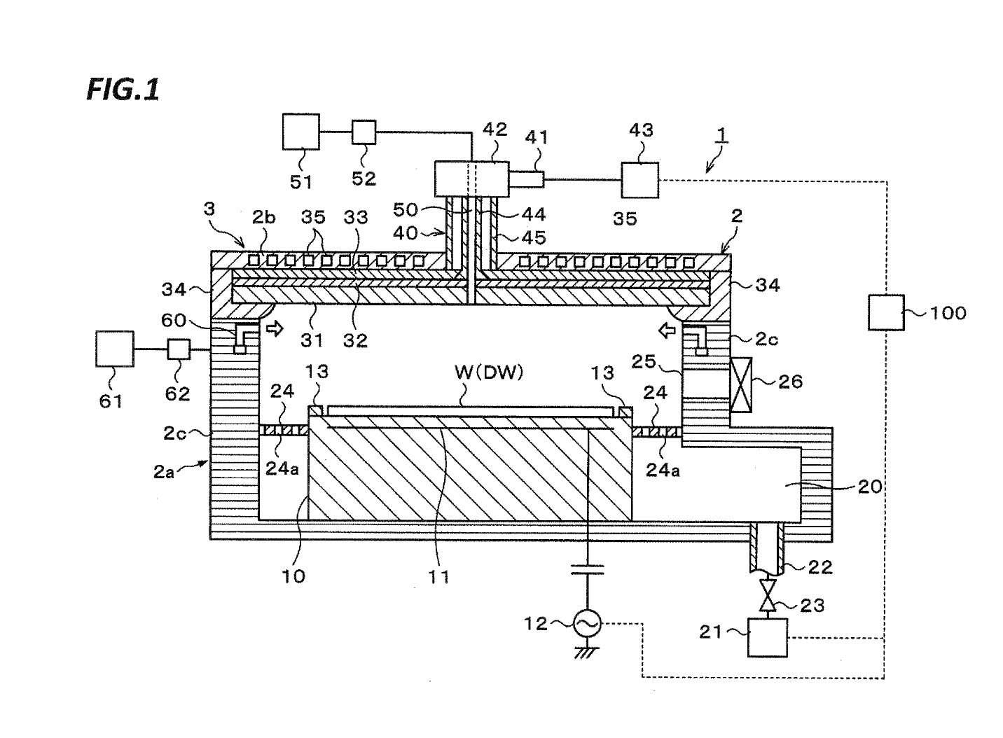

Hereinafter, an exemplary embodiment of the present disclosure will be described. FIG. 1 is a vertical sectional view illustrating a schematic configuration of a plasma processing apparatus 1 according to the exemplary embodiment. Further, the plasma processing apparatus 1 will be described with respect to a case where a plasma chemical vapor deposition (CVD) processing is performed on a surface of a wafer W serving as a substrate to form a SiN film (silicon nitride film) on the surface of the wafer W, by way of example. Further, in the specification and drawings, components having substantially the same configuration and function will be given the same symbols, and redundant descriptions will be omitted.

The plasma processing apparatus 1 includes a processing container 2 of which the inside is air-tightly maintained, and a radial line slot antenna 3 that supplies microwaves for plasma generation into the processing container 2. The processing container 2 includes a substantially cylindrical top-opened main body 2a, and a substantially disc-shaped cover 2b that air-tightly blocks the opening of the main body 2a. The main body 2a and the cover 2b are formed of a metal such as, for example, aluminum.

A susceptor 10 on which a wafer W is placed is provided on the bottom surface of the main body 2a of the processing container 2. The susceptor 10 is, for example, disc-shaped, and is formed of a metal such as, for example, aluminum. The susceptor 10 incorporates an electrode 11, and the electrode 11 is connected with a power source 12 that applies a voltage for attracting and holding the wafer W. Further, the power source 12 is configured to alternately apply a high voltage of, for example, ±1 kV to the electrode 11. Therefore, as a high voltage is intermittently applied by the power source 12 to generate an electromagnetic stress in the processing container 2, particles attached inside the processing container 2 may be scattered. Further, the susceptor 10 is connected with a high frequency power source for bias (not illustrated) via a matcher (not illustrated). The high frequency power source outputs a constant frequency suitable for controlling energy of ions drawn to the wafer W, for example, a high frequency of 13.56 MHz. Further, although not illustrated, a heater (not illustrated) is provided inside the susceptor 10 to heat the wafer W to a predetermined temperature.

Further, a lift pin (not illustrated) is provided below the susceptor 10 to support the wafer W from a lower side and lift the wafer W. The lift pin is configured to be projectable from the top surface of the susceptor 10 through a through-hole (not illustrated) formed in the susceptor 10.

An annular focus ring 13 is provided on the top surface of the susceptor 10 to surround the wafer W. The focus ring 13 is formed of an insulating material such as, for example, ceramic or quartz.

An exhaust chamber 20 is formed in the bottom portion of the main body 2a of the processing container 2 to project to, for example, a lateral side of the main body 2a. The bottom surface of the exhaust chamber 20 is connected with an exhaust mechanism 21 via an exhaust pipe 22 to exhaust an atmosphere inside the processing container 2. The exhaust pipe 22 is provided with an adjustment valve 23 that adjusts an exhaust amount by the exhaust mechanism 21.

Above the exhaust chamber 20, an annular baffle plate 24 is provided between an outer surface of the susceptor 19 and a sidewall 2c of the main body 2a to uniformly exhaust the atmosphere inside the processing container 2. The baffle plate 24 includes openings 24a formed over the entire circumference through the baffle plate 24 in a thickness direction.

A carry-in/out port 25 of the wafer W is formed above the baffle plate 24 in the sidewall 2c of the main body 2a of the processing container 2. The carry-in/out port 25 is provided with a gate valve 26 configured to be opened/closed. When the gate valve 26 is closed, the inside of the processing container 2 is air-tightly closed.

The radial line slot antenna 3 is provided in an opening of the ceiling surface of the processing container 2 to supply microwaves for plasma generation into the processing container 2. The radial line slot antenna 3 includes a microwave transmission plate 31, a slot plate 32, and a slow-wave plate 33. The microwave transmission plate 31, the slot plate 32, and the slow-wave plate 33 are stacked from the bottom in this order. The microwave transmission plate 31 is supported by an annular support member 34 provided to project inwardly from a periphery of an opening of the main body 2a of the processing container 2. A gap between the microwave transmission plate 31 and the support member 34 is air-tightly maintained by a sealing material (not illustrated) such as, for example, an O-ring. The microwave transmission plate 31 is formed of a dielectric such as, for example, quartz, Al₂O₃, or AlN, and has a function to transmit microwaves. The top surface of the slow-wave plate 33 is covered by the cover 2b.

A plurality of slots are formed in the slot plate 32 provided on the top surface of the microwave transmission plate 31, and the slot plate 32 functions as an antenna. The slot plate 32 is formed of a conductive material such as, for example, copper, aluminum, or nickel.

The slow-plate 33 provided on the top surface of the slot plate 32 is formed of a low-loss dielectric material such as, for example, quartz, Al₂O₃, or AlN, and has a function to shorten the wavelength of the microwaves.

In the cover 2b that covers the top surface of the slow-wave plate 33, a plurality of annular flow paths 35 are formed to circulate, for example, a cooling medium therethrough. The cover 2b, the microwave transmission plate 31, the slot plate 32, and the slow-wave plate 33 are adjusted to a predetermined temperature by the cooling medium that flows through the flow paths 35.

The central portion of the cover 2b is connected with a coaxial waveguide 40. The upper end portion of the coaxial waveguide 40 is connected with a microwave generation source 43 via a rectangular waveguide 41 and a mode converter 42. The microwave generation source 43 is provided outside the processing container 2, and is able to generate microwaves of, for example, 2.45 GHz.

The coaxial waveguide 40 includes an internal conductor 44 and an external pipe 45. The internal conductor 44 is connected to the slot plate 32. The slot plate 32 side of the internal conductor 44 is formed conically to efficiently propagate the microwaves to the slot plate 32.

With such a configuration, the microwaves generated from the microwave generation source 43 are sequentially propagated through the rectangular waveguide 41, the mode converter 42, and the coaxial waveguide 40, and compressed in the slow-wave plate 33 so that the wavelength is shorten. Then, circularly polarized microwaves from the slot plate 32 are transmitted through the microwave transmission plate 31 and irradiated into the processing container 2. A processing gas is converted into plasma in the processing container 2 by the microwaves, and the plasma processing of the wafer W is performed by the plasma.

A first gas supply pipe 50 is provided in the central portion of the ceiling surface of the processing container 2, that is, in the central portion of the radial line slot antenna 3. The first gas supply pipe 50 penetrates through the radial line slot antenna 3 in the vertical direction. One end portion of the first gas supply pipe 50 is opened in the bottom surface of the microwave transmission plate 31. Further, the first gas supply pipe 50 extends through the inside of the internal conductor 44 of the coaxial waveguide 40, and is inserted through the mode converter 42. The other end portion of the first gas supply pipe 50 is connected to a first gas supply source 51.

A processing gas, a purge gas, and a cleaning gas are individually stored in the first gas supply source 51. As the processing gas, for example, trisilylamine (TSA), N₂ gas, H₂ gas, and Ar gas are individually stored. Among these, TSA, N₂ gas, and H₂ gas are raw material gases for forming the SiN film. Ar gas is a gas for plasma excitation. As the cleaning gas, for example, CF₄ gas is stored.

The first gas supply pipe 50 is provided with a supply equipment group 52 including a valve or a flow rate adjusting unit that controls the flow of the gas in the first gas supply pipe 50. The processing gas or the cleaning gas supplied from the first gas supply source 51 is supplied into the processing container 2 through the first gas supply pipe 50, and flow vertically downwardly toward the wafer W placed on the susceptor 10.

Further, as illustrated in FIG. 1, second gas supply pipes 60 are provided in an inner peripheral surface in the upper portion of the processing container 2. A plurality of the second gas supply pipes 60 are provided at equal intervals along the inner peripheral surface of the processing container 2. The second supply pipes 60 are connected with a second gas supply source 61. In the second gas supply source 61, as the processing gas, for example, trisilylamine (TSA), N₂ gas, H₂ gas, and Ar gas are individually stored. As the purge gas, for example, nitrogen gas is stored. As the cleaning gas, for example, Cl or CF₄ gas is stored.

The second gas supply pipes 60 are provided with a supply equipment group 62 including a valve or a flow rate adjusting unit that controls the flow of the gas in the second gas supply pipes 60. The processing gas or the cleaning gas supplied from the second gas supply source 61 is supplied into the processing container 2 through the second gas supply pipes 60, and flows toward the outer peripheral portion of the wafer W placed on the susceptor 10. As such, the gas form the first gas supply pipe 50 is supplied toward the central portion of the wafer W, and the gas from the second gas supply pipe 60 is supplied toward the outer peripheral portion of the wafer W.

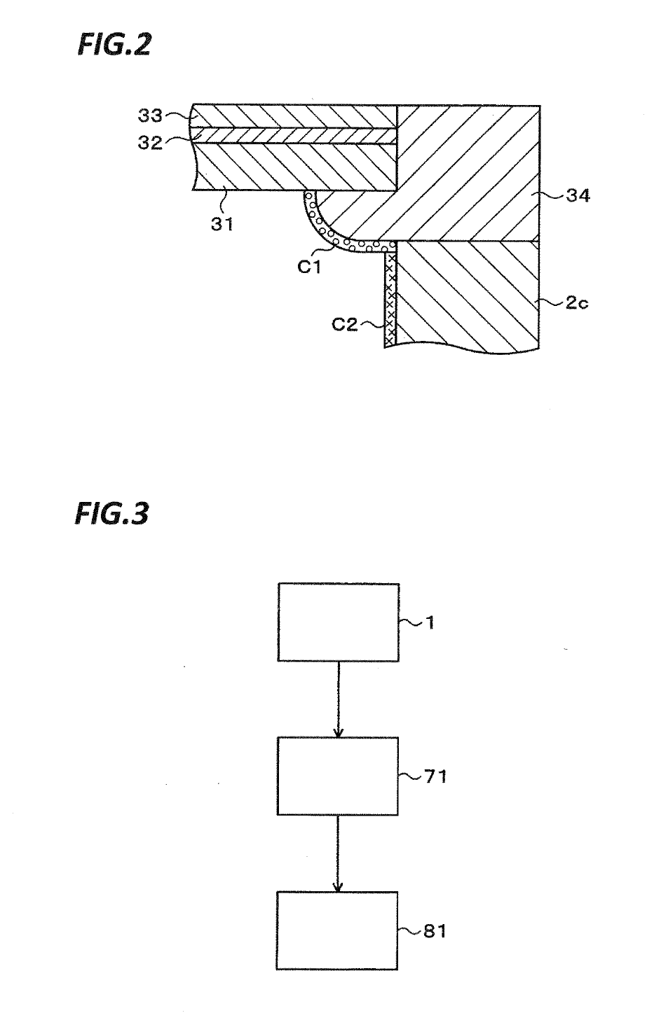

In addition, in the present exemplary embodiment, as illustrated in FIG. 2, the surface of the support member 34 that directly supports the microwave transmission plate 31 of the top plate portion, that is, the surface exposed to plasma is coated with a material having an excellent plasma resistance, thereby forming a film C1. In the present exemplary embodiment, yttria (yttrium oxide: Y₂O₃) having a high plasma resistance is employed as the material of the film C1. Meanwhile, the surface of the sidewall 2c of the main body 2a continued from the support member 34, that is, the surface exposed to plasma is coated with a material having an excellent plasma resistance, thereby forming a film C2. In the present exemplary embodiment, Al₂O₃ having a high plasma resistance is employed as the material of the film C2. As described above, in the present exemplary embodiment, the surface of the support member 34 that supports the top plate portion and the surface of the sidewall 2c continued from the support member 34 are coated with different materials, e.g., Y₂O₃ and Al₂O₃, respectively.

The above-described plasma processing apparatus 1 includes a controller 100 as illustrated in FIG. 1. The controller 100 is, for example, a computer, and includes a program storage unit (not illustrated). The program storage unit stores a program for controlling operations of the equipment such as an ultrasonic vibration generating mechanism 70 or the microwave generating source 43, and the respective gas supply sources 51, 61 to realize a plasma processing or a cleaning method (to be described later) of the plasma processing apparatus 1. Further, the program may be recorded in a computer-readable storage medium such as, for example, a computer-readable hard disc (HD), flexible disc (FD), compact disc (CD), optical disc (MO), or memory card, and may be installed to the controller 100 from the storage medium.

The plasma processing apparatus 1 according to the present exemplary embodiment is configured as described above. Next, descriptions will be made on a method for determining replacement of the members of the plasma processing apparatus 1 according to the present exemplary embodiment.

First, an ordinary plasma processing is performed on a product wafer W. For example, when a film formation processing is performed, a first processing gas and a second processing gas are supplied into the processing container 2, and the microwave generation source 43 is operated. The microwave generation source 43 generates microwaves of a predetermined power at a frequency of, for example, 2.45 GHz. The microwaves are irradiated into the processing container 2 via the rectangular waveguide 41, the mode converter 42, the coaxial waveguide 40, and the radial line slot antenna 3. The processing gases are converted into plasma in the processing container 2 by the microwaves, and dissociation of the processing gases proceeds in the plasma, so that a predetermined film is formed on the surface of the wafer W by radicals (active species) generated at that time.

While the plasma processing is performed on the wafer W, the susceptor 10 is applied with high frequency waves of a predetermined power at a frequency of, for example, 13.56 MHz by a high frequency power source (not illustrated). By applying RF bias in an appropriate range ions in the plasma may be drawn into the wafer W.

When the plasma processing is performed repeatedly, a film of reaction products is gradually attached to the inside of the processing container 2. Thus, for example, whenever a predetermined number of wafers W are processed, cleaning is performed by supplying a first cleaning gas and a second cleaning gas into the processing container 2.

Then, when such a periodic cleaning operation is done, for example, when the number of processed sheets reaches a predetermined number of sheets (e.g., thousands of sheets) or a predetermined number of lots, a replacement determination operation is performed as described below.

First, a dummy wafer DW serving as a simulation substrate is placed on the susceptor 10 in the processing container 2. Then, similarly to the case of the ordinary processing of the product wafer W, a predetermined gas is introduce into the processing container 2. Meanwhile, plasma is generated by a predetermined power. Then, a plasma processing is performed for the same period of time as the ordinary processing of the product wafer W.

Subsequently, the dummy wafer DW is carried out from the processing container 2, and conveyed to the particle counter 71 as illustrated in FIG. 2, so that the number of particles on the surface of the dummy wafer DW is measured. Based on the measurement result, when the number of particles does not reach a predetermined threshold N, it is determined that the replacement of each of the members in the processing container 2 is unnecessary.

On the contrary, based on the measurement result, when the number of particles is equal to or more than the predetermined threshold N, the dummy wafer DW is carried out from the particle counter 71, and conveyed to a component analyzer 81 so that the component of the particles on the surface of the dummy wafer DW is analyzed. Then, based on the analysis result, it is identified which member has the film from which the particle component causing the largest number of particles is originated within the processing container 2. In the present exemplary embodiment, as described above, the film C1 of the surface of the support member 34 is formed of Y₂O₃, and on the other hand, the film C2 of the surface of the sidewall 2c continued from the support member 34 is formed of Al₂O₃. Thus, based on the analysis result, for example, when the component of the most particles is Y₂O₃, it is determined that the surface of the support member 34 is deteriorated or corroded. When the component of the most particles is Al₂O₃, it is determined that the surface of the sidewall 2c is deteriorated or corroded. Therefore, in the former case, it is determined that the support member 34 is a member to be replaced, and in the latter case, it is determined that the sidewall 2c is a member to be replaced.

In this way, it is possible to identify a deteriorated or corroded member, and replace only a member which is necessary to replace. Therefore, the plasma processing apparatus 1 may be re-operated by replacing the member in a shorter time without spending any unnecessary cost, as compared with the conventional technique.

Further, as the component analyzer 81, for example, an energy dispersive X-ray spectrometer (EDX) may be used in combination with an electron microscope.

Further, the exemplary embodiment has been described with respect to an example in which the surfaces of the support member 34 and the sidewall 2c are coated with the films C1, C2 using different materials. This is because the two members were positioned in a high-plasma density region within the processing container of this type of plasma processing container, and have been corroded or deteriorated the most. However, the present disclosure is, of course, not limited thereto, and may be applied to other members of the processing container 2. In that case, the surfaces of the other members may have films formed by coating with other materials different from the materials of the films C1, C2.

As the members having films that are formed different materials, a member of the second gas supply pipe 2, which serves as a gas supply port to the processing container 2 and is exposed to plasma within the processing container 2, and the focus ring 13 and the baffle plate 24, which are positioned in a peripheral portion of the susceptor 10 and exposed to the substrate outer peripheral portion upon the placement of the wafer W, that is, exposed to plasma, may be exemplified. In such a case, as for the coating materials, it is necessary to use materials different from Y₂O₃ and Al₂O₃ as well as from each other. For example, AlN, YF, and PrO may be used. These are, of course, illustrative. The materials of the films C1, C2 of the surfaces of the support member 34 and the sidewall 2c are not limited to Y₂O₃ and Al₂O₃. As long as the respective coating materials of the focus ring 13 and the baffle plate 24 are different from each other, any kind of coating materials may be arbitrarily used.

Further, in the exemplary embodiment, the dummy wafer DW was subjected to the same plasma processing as the ordinary processing of the product wafer W, but not limited thereto. It is possible to introduce an inert gas (e.g., Ar, He, or N₂) into the processing container 2 to generate plasma, and then, similarly to the above-described exemplary embodiment, convey the dummy wafer DW to the particle counter 71. Thereafter, determination based on the threshold N, conveyance to the component analyzer 81 according to the result, and determination based on the component analysis, may be performed by implementing the same procedure. Thus, as compared with the case of performing the same plasma processing as the ordinary processing of the product wafer W, the time within the processing container 2 may be reduced, so that the time to reach the determination is reduced.

Moreover, it is possible to merely supply an inert gas (e.g., Ar, He, or N₂) into the processing container 2 without generating plasma. Then, similarly to the above-described exemplary embodiment, conveyance to the particle counter 71, determination based on the threshold N, further conveyance to the component analyzer 81 according to the result, and determination based on the component analysis, may be performed. Thus, the time to reach the determination may be further reduced. As such, the coating material may flake off from the surface of a member just by the gas supply in some cases. In such cases, a subsequent necessary determination may be performed by the gas supply only.

Further, as described above with respect to the dummy wafer DW, it is possible to arbitrarily select whether to perform the same plasma processing as the ordinary processing of the product wafer W, whether to simply generate plasma in the processing container 2, or whether to perform a subsequent respective determination by supplying gas only. The selection may be made appropriately depending on the kind of coating material, the integrated number of processed sheets, the integrated processing time, or the kind of plasma processing. However, in the case of performing the same plasma processing as the ordinary processing of the product wafer W, in the case of simply generating plasma, and in the case of supplying gas only, since respective particle generation amounts are different from each other, the threshold N and a threshold M (to be described below) may be individually set appropriately depending on each case.

Furthermore, in the above-described exemplary embodiment, it is identified, based on the analysis, which member has a film from which the particle component causing the largest number of particles is originated from its film within the processing container 2, but not limited thereto. All the members coated with a coating material having a component of which the number of particles exceeds a predetermined threshold M, may be determined as members to be replaced. By doing this, for example, a member which has not the largest number of particles is but is actually in a state to be replaced may also be identified. That is, it is possible to determine replacement of a plurality of members at the same time as well as to determine replacement of one member.

The above-described exemplary embodiment exemplifies a film forming apparatus in which plasma is generated by microwaves. However, without being limited to the film forming apparatus, the present disclosure may be applied to an etching apparatus, or a sputtering apparatus. Further, the present disclosure may be applied to a plasma processing apparatus that generates plasma by other means, without being limited to microwaves, such as, for example, parallel flat plate type plasma or ICP plasma. In addition, the substrate is not limited to a wafer, but may be a glass substrate, an organic EL substrate, or a substrate for flat panel display (FPD).

The present disclosure is useful for, for example, an apparatus that performs a plasma processing on a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container configured to air-tightly accommodate a substrate; and
a placing table provided in the processing container and configured to place the substrate thereon,
wherein a surface of a support member that is exposed to plasma in the processing container and configured to support a top plate portion of the processing container, and a surface of a member that is exposed to plasma in the processing container and continued from the support member, are coated with different materials.

2. The plasma processing apparatus of claim 1, wherein a gas supply port configured to supply a gas is provided within the processing container, and
a surface of the gas supply port that is exposed to plasma is coated with a different material from those of the respective surfaces.

3. The plasma processing apparatus of claim 1, wherein a surface of the placing table that is exposed from an outer peripheral portion of the substrate to be exposed to plasma when the substrate is placed on the placing table, is coated with a different material from that of each of the surfaces.

4. The plasma processing apparatus of claim 1, wherein a baffle plate is provided within the processing container, and
a surface of the baffle plate that is exposed to plasma is coated with a different material from those of the respective surfaces.

5. A method for determining replacement of a member of a plasma processing apparatus claimed in claim 1, the method comprising:
placing a simulation substrate on the placing table;
supplying a predetermined gas into the processing container, or converting the predetermined gas into plasma in the processing container;
measuring the number of particles on the simulation substrate by a particle counter;
performing a component analysis of the particles on the simulation substrate when the number of particles exceeds a predetermined value, based on the measurement result; and
determining that a member coated with a coating material including a component having the largest number of particles is a member to be replaced, based on the analysis result.

6. A method for determining replacement of a member of a plasma processing apparatus claimed in claim 1, the method comprising:
placing a simulation substrate on the placing table;
supplying a predetermined gas, or converting the predetermined gas into plasma;
measuring the number of particles on the simulation substrate by a particle counter;
performing a component analysis of the particles on the simulation substrate when the number of particles exceeds a predetermined value, based on the measurement result; and
determining that a member coated with a coating material including a component of which the number of particles exceeds a predetermined threshold is a member to be replaced, based on the analysis result.
